(19) United States
(12) Patent Application Publication
(10) Pub. No.: US 2026/0068601 A1
(43) Pub. Date: Mar. 5, 2026

(54) SUBSTRATE SUPPORT APPARATUS

(71) Applicant: SAMSUNG ELECTRONICS CO., LTD., Suwon-si, Gyeonggi-do (KR)

(72) Inventors: Gaeul KIM, Suwon-si (KR); Donghoon KWON, Suwon-si (KR)

(21) Appl. No.: 19/012,559

(22) Filed: Jan. 7, 2025

(30) Foreign Application Priority Data
Sep. 4, 2024 (KR) 10-2024-0120177

(51) Int. Cl. H01L 21/687

(52) U.S. Cl. CPC H01L 21/68785

(57) ABSTRACT

Some embodiments of the present disclosure provide a substrate support apparatus including a support member configured to support a substrate on a substrate support surface, wherein the support member has a plurality of injection holes, each having a first end that is positioned on the substrate support surface and configured to inject a cleaning gas, and a plurality of exhaust holes, each having a first end that is positioned on the substrate support surface and configured to enable exhaust.

### CROSS-REFERENCE TO RELATED APPLICATION

This application claims priority to and the benefit of Korean Patent Application No. 10-2024-0120177, filed in the Korean Intellectual Property Office on Sep. 4, 2024, the entire contents of which are incorporated herein by reference.

### BACKGROUND

The present disclosure relates to a substrate support apparatus.

Semiconductor devices are manufactured through various processes, including a photolithography process, which forms a circuit pattern on a substrate such as a silicon wafer, as well as an etching process, a deposition process, and a cleaning process. Each of these processes may be performed inside substrate processing equipment.

Substrate processing equipment may have an equipment front end module (EFEM) positioned at one side, through which substrates are fed into the facility or removed from the equipment. Furthermore, multiple chambers may be positioned within the substrate processing equipment.

### SUMMARY

Example embodiments of the present disclosure provide a substrate support apparatus capable of effectively supporting a substrate.

However, the problem(s) to be solved by the example embodiments of the present disclosure is not limited to the above-described problem(s), and can be variously extended or modified within the scope of the technical spirit and scope of the present disclosure.

An aspect of the present disclosure provides a substrate support apparatus including a support member configured to support a substrate on a substrate support surface, wherein the support member has a plurality of injection holes, each having a first end that is positioned on the substrate support surface and configured to inject a cleaning gas, and a plurality of exhaust holes, each having a first end that is positioned on the substrate support surface and configured to enable exhaust.

Another aspect of the present disclosure provides a substrate support apparatus including: a support member configured to support a substrate on a substrate support surface; a heater facing the support member and spaced apart from the support member; and a transfer arm connected to the support member and the heater, wherein the support member has a plurality of injection holes, each having a first end that is positioned on the substrate support surface and configured to inject a cleaning gas, and a plurality of exhaust holes, each having a first end that is positioned on the substrate support surface and configured to enable exhaust.

Another aspect of the present disclosure provides a substrate support apparatus including: a housing; a support member inside the housing and configured to support a substrate on a substrate support surface; a heater inside the housing spaced apart from the support member; and a transfer arm connected to the housing, wherein the support member has a plurality of injection holes, each having a first end that is positioned on the substrate support surface and configured to inject a cleaning gas that is at least partially phase-changed into a solid state by adiabatic expansion after being injected, and a plurality of exhaust holes, each having a first end that is positioned on the substrate support surface and configured to enable exhaust.

According to the example embodiments, a substrate support apparatus capable of effectively supporting a substrate may be provided.

### BRIEF DESCRIPTION OF THE DRAWINGS

FIG. 1 illustrates a perspective view of a substrate support apparatus according to some embodiments.

FIG. 2 illustrates a cross-sectional view of a substrate support apparatus according to some embodiments.

FIG. 3 illustrates a perspective view of a support member of FIG. 2.

FIG. 4 illustrates a top plan view of the support member of FIG. 2.

FIG. 5 illustrates a cleaning hole positioned within a unit area of an upper surface of the support member of FIG. 2.

FIG. 6 illustrates a state in which cleaning is performed while a substrate is positioned on a support member of a substrate support apparatus according to some embodiments.

FIG. 7 illustrates a portion of an upper surface of a support member according to some embodiments.

FIG. 8 illustrates a portion of an upper surface of a support member according to some embodiments.

FIG. 9 illustrates an upper surface of a support member according to some embodiments.

FIG. 10 illustrates a portion of an upper surface of a support member according to some embodiments.

FIG. 11 illustrates a cross-sectional view of a support member according to some embodiments.

FIG. 12 illustrates a cross-sectional view of a support member according to some embodiments.

FIG. 13 illustrates a cross-sectional view of a support member according to some embodiments.

FIG. 14 illustrates a cross-sectional view of a support member according to some embodiments.

FIG. 15 illustrates a heater according to some embodiments.

FIG. 16 illustrates a perspective view of a substrate support apparatus according to some embodiments.

### DETAILED DESCRIPTION

The present disclosure will be described more fully hereinafter with reference to the accompanying drawings, in which example embodiments of the disclosure are shown. As those skilled in the art would realize, the described embodiments may be modified in various different ways, all without departing from the spirit or scope of the present disclosure.

To clearly describe the present disclosure, parts that are irrelevant to the description may be omitted, and like numerals refer to like or similar components throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thicknesses of layers, films, panels, regions, etc., may be exaggerated for clarity. In the drawings, for better understanding and ease of description, the thicknesses of some layers and areas may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” means when an object portion is viewed from above, and the phrase “in a cross-sectional view” means when a cross-section taken by vertically cutting an object portion is viewed from the side.

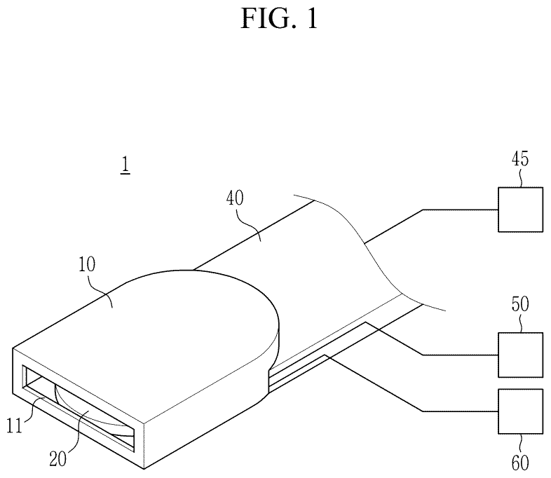

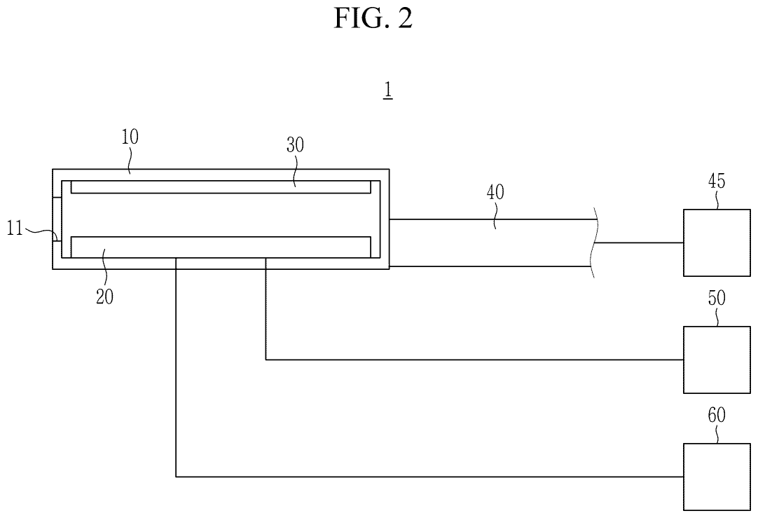

FIG. 1 illustrates a perspective view of a substrate support apparatus 1 according to some embodiments, and FIG. 2 illustrates a cross-sectional view of the substrate support apparatus 1 according to some embodiments.

Referring to FIGS. 1 and 2, the substrate support apparatus 1 according to some embodiments may include a housing 10, a support member 20, a heater 30, and a transfer arm 40.

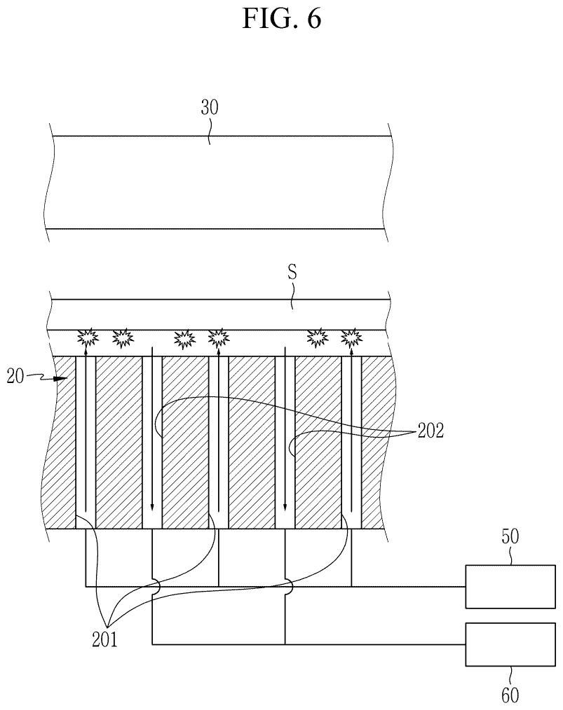

The substrate support apparatus 1 may support a substrate S (see, e.g., FIG. 6). The substrate support apparatus 1 may perform cleaning on the substrate S while supporting the substrate S. The substrate support apparatus 1 may perform cleaning on a lower surface of the substrate S. The substrate S may be a wafer or the like for manufacturing a semiconductor device.

The substrate support apparatus 1 may be disposed inside a substrate processing equipment. That is, the substrate support apparatus 1 may be included as one component in the substrate processing equipment. The substrate processing equipment may perform a set process on the substrate S. For example, the substrate processing equipment may perform a chemical mechanical polishing process, a photoresist application process, an exposure process, a development process, an etching process, a deposition process, etc. on the substrate S. Substrate(S) processing may be performed in a state where an atmospheric pressure of the substrate processing equipment is reduced to a pressure that is lower than the atmospheric pressure. Accordingly, when the substrate support apparatus 1 supports the substrate S, the substrate support apparatus 1 may be disposed in a space having a pressure lower than the atmospheric pressure.

The housing 10 may have a predetermined volume. A receiving space capable of accommodating the substrate S may be positioned inside the housing 10. An opening 11 may be positioned at a first side or front side of the housing 10 through which the substrate S can be brought into or taken out of the receiving space. The opening 11 may be positioned at a first side of a side wall of the housing 10.

The support member 20 may be disposed inside the housing 10. The support member 20 may be disposed at a lower portion of the receiving space. The support member 20 may be connected to the housing 10. The support member 20 may be provided such that at least a portion of the support member 20 is in contact with the housing 10, and may be connected to the housing 10. For example, the support member 20 may be provided such that a lower surface thereof contacts the housing 10, and may be connected to the housing 10. An upper surface of the support member may be provided to be exposed toward an upper space. The substrate S may be positioned on the upper surface of the support member 20. Accordingly, the upper surface of the support member 20 may be referred to as a substrate support surface. An area and a shape of the upper surface of the support member 20 may correspond to an area and a shape of an upper or lower surface of the substrate S.

The support member 20 may be connected to a fluid supply member 50. The fluid supply member 50 may supply a cleaning gas to the support member 20 such that the cleaning gas is sprayed toward an upper space from the upper surface of the support member 20. The cleaning gas may be an inert gas. For example, the cleaning gas may be a gas selected from nitrogen, argon, neon, helium, or a combination thereof. The fluid supply member 50 may be provided in a low-temperature insulating container structure. Accordingly, the cleaning gas stored in the fluid supply member 50 may be at least partially in a liquid state.

The support member 20 may be connected to an exhaust member 60. The exhaust member 60 may generate a negative pressure in a space positioned on an upper surface of the support member 20 through the support member 20. Forced exhaust may be performed on the space positioned on the upper surface of the support member 20 by the negative pressure generated on the upper surface of the support member 20. Accordingly, fluid, particles, etc. may be forcibly exhausted from the space positioned on the upper surface of the support member 20. Additionally, the substrate S may be fixed to the support member 20 by the negative pressure generated on the upper surface of the support member 20. For example, the exhaust member 60 may include a pump, etc.

The heater 30 may be disposed inside the housing 10. The heater 30 may be disposed at an upper portion of the receiving space, separately or spaced apart from the support member 20. The heater 30 may be disposed above the support member 20. The heater 30 may face the upper surface of the support member 20. A shape of a lower surface of the heater 30 may correspond to a shape of the upper surface of the support member 20. An area of the lower surface of the heater 30 may correspond to an area of the upper surface of supporting member 20. A shape of the lower surface of the heater 30 may correspond to a shape of the upper or lower surface of the substrate S. The area of the lower surface of the heater 30 may correspond to an area of the upper or lower surface of the substrate S.

The heater 30 may be connected to the housing 10. The heater 30 may be provided such that at least a portion thereof is in contact with the housing 10, and may be connected to the housing 10. For example, the heater 30 may be connected to the housing 10 such that at least a portion of an upper surface thereof or at least a portion of a side surface thereof is provided to contact the housing 10. The lower surface of the heater 30 may be provided to be exposed toward a lower space. Accordingly, the lower surface of the heater 30 may face the upper surface of the supporting member and the substrate S positioned on the supporting member 20 in the vertical direction.

The heater 30 may be or include a light emitting diode (LED) lamp, an infrared (IR) lamp, a laser irradiation module, a microwave irradiation module, etc. The heater may be configured to be turned on and off. The heater 30 may heat the substrate S positioned on the supporting member 20 by irradiating a heat energy source toward the supporting member 20. The heat energy source may be light, microwaves, etc. irradiated by the heater 30.

The transfer arm 40 may be connected to the housing 10. For example, the transfer arm 40 may be connected to the housing 10 in an opposite direction of the opening 11 with respect to the support member 20 (e.g., a back or rear side of the housing). The supporting member 20 may be connected to the transfer arm 40 through the housing 10. Furthermore, the heater 30 may be connected to the transfer arm 40 through the housing 10. The transfer arm 40 may be provided movably.

The transfer arm 40 may be connected to a driving member 45. The driving member 45 may provide power to move the transfer arm 40, the housing 10, the support member 20, and the heater 30 connected to the transfer arm 40. For example, the driving member 45 may include a motor, a hydraulic cylinder, or the like.

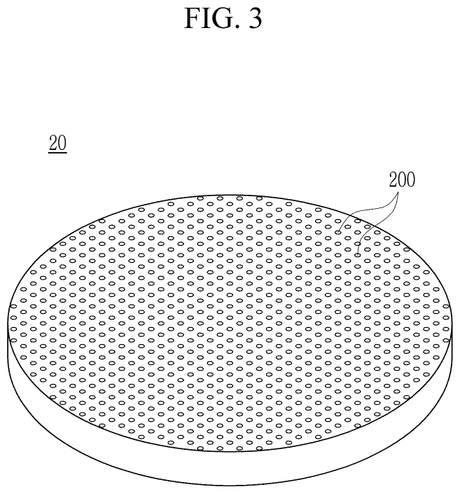

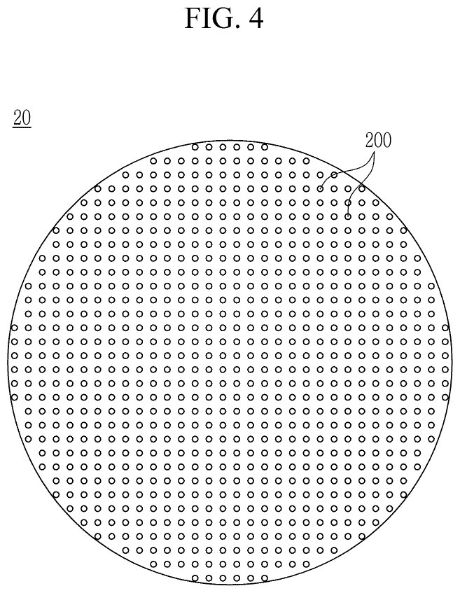

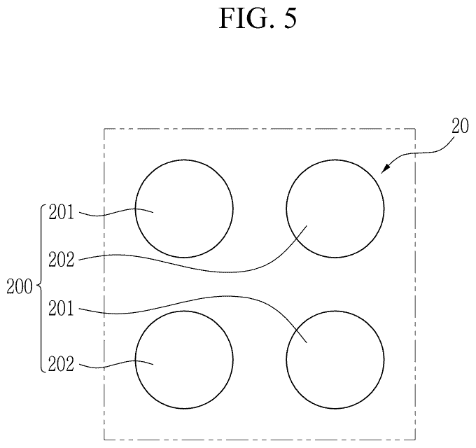

FIG. 3 illustrates a perspective view of the support member 20 of FIG. 2, FIG. 4 illustrates a top plan view of the support member 20 of FIG. 2, and FIG. 5 illustrates a cleaning hole or cleaning channel or cleaning nozzle 200 positioned within a unit area of an upper surface of the support member 20 of FIG. 2.

Referring to FIGS. 3 to 5, the support member 20 may enable cleaning of the substrate S positioned on the support member 20 through a cleaning gas. The support member 20 may enable cleaning to be performed on the substrate S positioned on the support member 20 through an aerosol formed by the cleaning gas. In the support member 20, the cleaning hole 200 may be positioned. The cleaning hole 200 may include an injection hole or injection channel or injection nozzle 201 and an exhaust hole or exhaust channel or exhaust nozzle 202.

A plurality of injection holes 201 may be provided. The injection hole 201 may be formed to extend through an inside of the support member 20, and may be positioned inside the support member 20. For example, the injection hole 201 may be provided to extend though at least a portion of the support member 20 in a vertical direction. An upper end of the injection hole 201 may be positioned on the upper surface of the support member 20. Accordingly, the upper end of the injection hole 201 may be connected to a space positioned on the upper surface of the support member 20.

The injection hole 201 may be connected to the fluid supply member 50. For example, the fluid supply member 50 may be connected to a lower end portion of the injection hole 201. Accordingly, the cleaning gas supplied by the fluid supply member 50 may be injected from the upper surface of the supporting member 20 to a space positioned on the upper surface of the support member 20 through the injection hole 201.

A plurality of exhaust holes 202 may be provided. The exhaust hole 202 may be formed to extend through an inside of the support member 20, and may be positioned inside the support member 20. For example, the exhaust hole 202 may be provided to extend though at least a portion of the support member 20 in the vertical direction. An upper end of the exhaust hole 202 may be positioned on the upper surface of the support member 20. Accordingly, the upper end of the exhaust hole 202 may be connected to a space positioned on the upper surface of the support member 20.

The exhaust hole 202 may be connected to the exhaust member 60. For example, the exhaust member 60 may be connected to a lower end portion of the injection hole 202. Accordingly, as the exhaust member 60 performs exhaust for the exhaust hole 202, negative pressure may be generated in a space positioned on an upper side of the exhaust member 60 and an upper surface of the support member 20. Furthermore, fluid, particles, etc. may be exhausted through the exhaust hole 202 in the space positioned on the upper surface of the support member 20.

A plurality of injection holes 201 may be distributed such that upper ends thereof are positioned differently on the upper surface of the support member 20. For example, numbers of upper ends of the injection holes 201 positioned within a unit area of the upper surface of the support member 20 may correspond to each other.

A plurality of exhaust holes 202 may be distributed such that upper ends thereof are positioned differently on the upper surface of the support member 20. For example, numbers of upper ends of the exhaust holes 202 positioned within a unit area of the upper surface of the support member 20 may correspond to each other.

The numbers of the upper ends of the exhaust holes 202 positioned within the unit area of the upper surface of the support member 20 may be equal to the numbers of the upper ends of the injection holes 201 positioned within the unit area of the upper surface of the support member 20. For example, the upper end of one exhaust hole 202 and the upper end of one injection hole 201 within the unit area of the upper surface of the supporting member 20 may be positioned adjacent to each other to match each other.

In contrast, numbers of upper ends of the exhaust holes 202 positioned within the unit area of the upper surface of the supporting member 20 may be greater than numbers of upper ends of the injection holes 201 positioned within the unit area of the upper surface of the supporting member 20. In addition, the numbers of the upper ends of the exhaust holes 202 positioned within the unit area of the upper surface of the support member 20 may be smaller than the numbers of the upper ends of the injection holes 201 positioned within the unit area of the upper surface of the support member 20.

FIG. 6 illustrates a state in which cleaning is performed while the substrate S is positioned on the support member 20 of the substrate support apparatus 1 according to some embodiments.

Referring to FIG. 6, the substrate S may be loaded onto the substrate support apparatus 1 and positioned on the supporting member 20.

The substrate S loaded onto the substrate support apparatus 1 may be in a state prior to process treatment after being brought into an inside of the substrate processing equipment. For example, the substrate S loaded onto the substrate support apparatus 1 may be transported to the substrate processing equipment through an index module and then returned to a process chamber included in the substrate processing equipment. In this case, the index module may indicate a portion disposed at a first end of the substrate processing equipment, through which the substrate S is brought into the substrate processing equipment or taken out from the inside of the substrate processing equipment. For example, the index module may be an equipment front end module (EFEM).

In this case, the substrate support apparatus 1 may be included in the substrate processing equipment, and may be disposed between the index module and a process chamber based on a path along which the substrate S moves. Furthermore, when the substrate S is loaded, the support member 20 may be moved from a region adjacent to the index module to a region adjacent to the process chamber as the transfer arm 40 is moved by the driving member 45. Thereafter, the substrate S may be unloaded from the support member 20 of the substrate support apparatus 1, and then introduced into the process chamber.

Furthermore, the substrate S loaded onto the substrate support apparatus 1 may have undergone a process treatment inside the substrate processing equipment. For example, the substrate S loaded onto the substrate support apparatus 1 may be returned to the index module after being removed from the process chamber included in the substrate processing equipment.

In this case, the substrate support apparatus 1 may be included in the substrate processing equipment, and may be disposed between the process chamber and the index module based on the path along which the substrate S moves. Furthermore, when the substrate S is loaded, the support member 20 may be moved from a region adjacent to the process chamber to a region adjacent to the index module as the transfer arm 40 is moved by the driving member 45. Thereafter, the substrate S may be unloaded from the support member 20 of the substrate support apparatus 1 and then returned to the index module.

Furthermore, the substrate S loaded onto the substrate support apparatus 1 may be for movement within the substrate processing equipment. For example, the substrate S loaded onto the substrate support apparatus 1 may be prior to an additional process treatment after the process treatment has been performed. That is, the substrate S loaded onto the substrate support apparatus 1 may be transported to another process chamber after being taken out of the process chamber.

In this case, the substrate support apparatus 1 may be included in the substrate processing equipment, and may be disposed between the process chamber and the process chamber based on the path along which the substrate S moves. Furthermore, when the substrate S is loaded, the support member 20 may be moved from a region adjacent to one process chamber to a region adjacent to another process chamber as the transfer arm 40 is moved by the driving member 45. Thereafter, the substrate S may be unloaded from the support member 20 of the substrate support apparatus 1, and then introduced into the process chamber.

A process of loading the substrate S into the substrate support apparatus 1 and a process of removing the substrate S from the substrate support apparatus 1 may be assisted by a robot arm included in the substrate processing equipment.

When the substrate S is positioned on the support member 20, the exhaust member 60 may perform exhaust for the exhaust hole 202. Accordingly, negative pressure may be generated and exhaust may be performed in a space positioned on an upper end of the exhaust member 60 and an upper surface of the support member 20. The substrate S may be fixed to the support member 20 by the negative pressure generated on the upper surface of the support member 20, so as to be prevented from being arbitrarily detached from the support member 20.

When the substrate S is positioned on the support member 20, the fluid supply member 50 may supply a cleaning gas to the injection hole 201 such that the cleaning gas is sprayed toward an upper space from the upper surface of the support member 20. In a state where the exhaust member 60 performs exhaust to the exhaust hole 202, the fluid supply member 50 may start supplying a cleaning gas to the injection hole 201. That is, after the exhaust member 60 starts exhausting to the exhaust hole 202, the fluid supply member 50 may start supplying the cleaning gas to the injection hole 201. Furthermore, exhaust of the exhaust hole 202 by the exhaust member 60 and supply of the cleaning gas by the fluid supply member 50 may be performed together or concurrently.

The cleaning gas injected from the injection hole 201 of the supporting member may perform cleaning on the substrate S. At least some of the cleaning gas injected from the injection hole 201 of the support member 20 may form an aerosol. Furthermore, the cleaning gas in an aerosol state may collide with a lower surface of the substrate S to perform cleaning on the lower surface of the substrate S.

Specifically, an inside of the substrate processing equipment where the substrate support apparatus 1 is disposed may be maintained at a pressure that is lower than an atmospheric pressure. For example, the inside of the substrate processing equipment may be maintained at a vacuum or a near-vacuum pressure. Furthermore, by performing exhaust through the exhaust hole 202, pressure in the space on the upper surface of the support member 20 may be lowered compared to when there is no exhaust through the exhaust hole 202. Accordingly, the cleaning gas injected into the space on the upper surface of the support member 20 from the injection hole 201 may undergo adiabatic expansion, and during a process of the adiabatic expansion, at least some of the cleaning gas may become a solid state. Furthermore, at least some of the cleaning gas which is in a solid state may collide with the substrate S, thereby performing more effective cleaning on the substrate S. That is, the solid-state cleaning gas may generate a greater impact force during the collision process with the substrate S than the gas-state cleaning gas, so particles, etc. attached to the substrate S may be more effectively removed from the substrate S. Furthermore, cleaning gas on the upper surface of the support member 20, particles removed from the substrate S, etc. may be exhausted through the exhaust hole 202 and removed from the space on the upper surface of the support member 20.

When the substrate S is positioned on the support member 20, the heater 30 may irradiate a thermal energy source toward the support member 20 and the substrate S positioned on the support member 20, thereby heating the substrate S.

When the fluid supply member 50 supplies cleaning gas and the cleaning gas is injected from the injection hole 201, the heater 30 may be turned on to start heating the space on the support member 20 and the substrate S. That is, the fluid supply member 50 may first start supplying the cleaning gas, and then the heater 30 may be turned on to start heating the space on the support member 20 and the substrate S. Furthermore, supply of the cleaning gas by the fluid supply member 50 and turning on of the heater 30 may be performed together or concurrently. Furthermore, while the heater 30 is turned to heat the space on the support member 20 and the substrate S, the supply of the cleaning gas by the fluid supply member 50 may begin.

The cleaning gas injected into the space on the supporting member 20 may be heated by the heater 30. The cleaning gas may be heated by an amount of heat transferred from the substrate S during the process of colliding with the substrate S. Furthermore, the cleaning gas may be heated by the thermal energy source irradiated by the heater 30. Upon heating, the cleaning gas may become a gas. Specifically, the cleaning gas that has been in a solid state by adiabatic expansion may change into a gaseous state by heating. In this case, a phase change in which the cleaning gas becomes a solid state by adiabatic expansion may occur when the cleaning gas is injected toward the substrate S from the injection hole 201. Accordingly, the cleaning gas may be injected from the injection hole 201, and then collide with the substrate S in an aerosol state to perform cleaning, and then may be heated to be phase-changed into a gaseous state. Accordingly, the cleaning gas that collides with the substrate S, particles removed from the substrate S, etc. may be effectively exhausted through the exhaust hole 202 to be removed from the space on the support member 20.

Furthermore, when the cleaning gas is supplied, the substrate S may be in a floating state with respect to the upper surface of the support member 20 where the injection hole 201 is positioned. That is, the substrate S may be maintained apart from the upper surface of the support member 20 in a region where the injection hole 201 is positioned while being prevented from being separated from the upper surface of the support member 20 by negative pressure generated on the support member 20 due to exhaust through the exhaust hole 202.

Furthermore, injection of the cleaning gas through the injection hole 201 may be performed during the process in which the support member 20 moves inside the substrate processing equipment as the transfer arm 40 moves by the driving member 45. Accordingly, the substrate support apparatus 1 may clean the substrate S while returning the substrate S inside the substrate processing equipment.

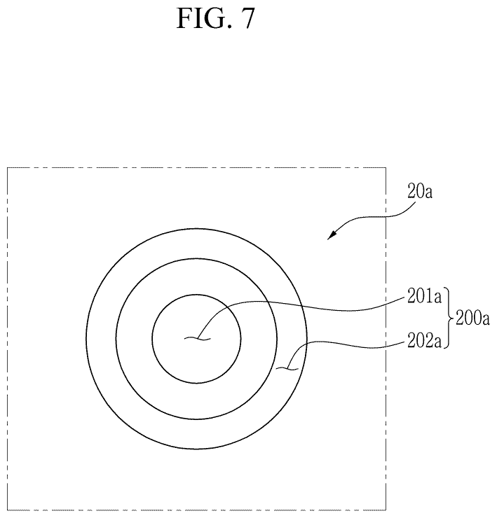

FIG. 7 illustrates a portion of an upper surface of a support member 20a according to some embodiments.

Referring to FIG. 7, an upper end of an exhaust hole 202a may be positioned at an outer circumference or outer circumferential region of an upper end of an injection hole 201a. Specifically, an upper end of the exhaust hole 202a may be provided in a ring structure. For example, the upper end of the exhaust hole 202a may have a structure such as a circular ring, an elliptical ring, a polygonal ring, etc. Furthermore, the upper end of the injection hole 201a may be positioned in an inner region or central region of the upper end of the exhaust hole 202a. A plurality of exhaust holes 202a may be in the outer circumference and/or a plurality of injection holes 201a may be in the inner region.

Accordingly, the cleaning gas injected from the injection hole 201a may be effectively discharged together with particles and the like through the exhaust hole 202a positioned at the outer circumference of the upper end of the injection hole 201a after colliding with the substrate S.

A remaining structure and an operating process of the support member 20a are identical or similar to those described above in FIGS. 1 to 6, so repeated descriptions will be omitted in the interest of brevity.

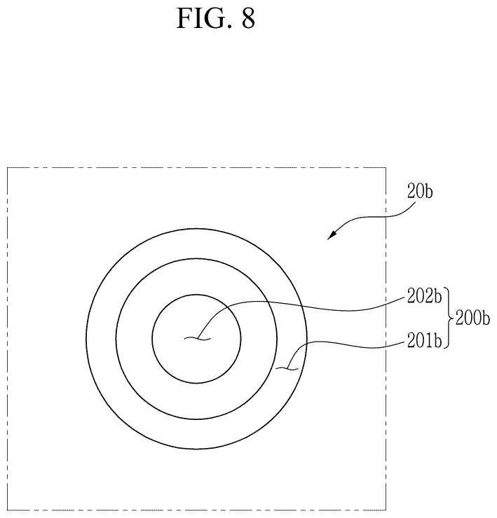

FIG. 8 illustrates a portion of an upper surface of a support member 20b according to some embodiments.

Referring to FIG. 8, an upper end of an injection hole 201b may be positioned at an outer circumference or outer circumferential region of an upper end of an exhaust hole 202b. Specifically, an upper end of the injection hole 201b may be provided in a ring structure. For example, the upper end of the injection hole 201b may have a structure such as a circular ring, an elliptical ring, a polygonal ring, etc. Furthermore, the upper end of the exhaust hole 202b may be positioned in an inner region or central region of the upper end of the injection hole 201b. A plurality of injection holes 201b may be in the outer circumference and/or a plurality of exhaust holes 202b may be in the inner region.

Accordingly, the cleaning gas injected from the injection hole 201b may be effectively discharged together with particles and the like through the exhaust hole 202b positioned at an inner region of the upper end of the injection hole 201b after colliding with the substrate S.

A remaining structure and an operating process of the support member 20b are identical or similar to those described above in FIGS. 1 to 6, so repeated descriptions will be omitted in the interest of brevity.

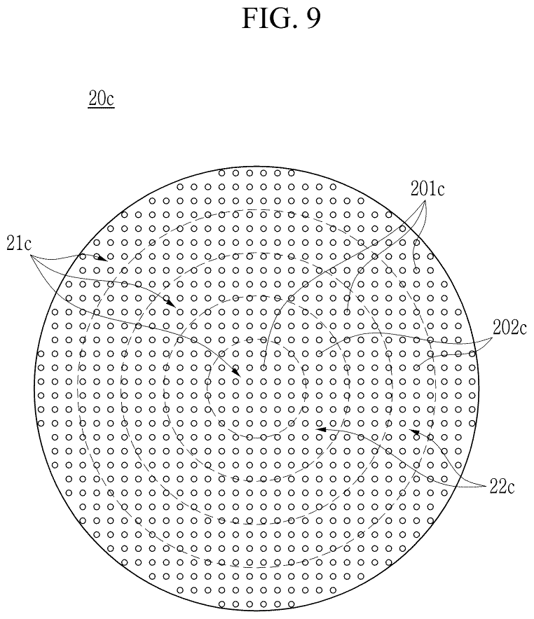

FIG. 9 illustrates an upper surface of a support member 20c according to some embodiments.

Referring to FIG. 9, an upper surface of the supporting member 20c may include an injection region 21c and an exhaust region 22c. An upper end of the injection hole 201c may be positioned in the injection region 21c. An upper end of the exhaust hole 202c may be positioned in the exhaust region 22c.

The injection region 21c and the exhaust region 22c may be arranged to form a concentric circle or concentric rings. In this case, widths of the injection region 21c and the exhaust region 22c along a radial direction may be the same or different. Furthermore, a plurality of injection regions 21c may be provided. In this case, the exhaust region 22c may be positioned between the injection regions 21c based on the radial direction. Widths of the injection regions 21c along the radial direction may be the same or different from each other.

Furthermore, a plurality of exhaust regions 22c may be provided. In this case, the injection region 21c may be positioned between the exhaust regions 22c based on the radial direction. Widths of the exhaust regions 22c along the radial direction may be the same or different from each other.

The injection regions 21c and the exhaust regions 22c may be arranged alternately in a radial direction. An injection region 21c may be in a central region, and the exhaust regions 22c and additional injection regions 21c may be alternately arranged as concentric rings in a radial direction. Alternatively, an exhaust region 22c may be in a central region, and the injection regions 21c and additional exhaust regions 22c may be alternately arranged as concentric rings in a radial direction.

FIG. 9 illustrates an example where the injection region 21c is positioned in a central region of an upper surface of the support member 20c. However, in contrast, the exhaust region 22c may be positioned in the central region of the upper surface of the support member 20c.

A remaining structure and an operating process of the support member 20c are identical or similar to those described above in FIGS. 1 to 6, so repeated descriptions will be omitted in the interest of brevity.

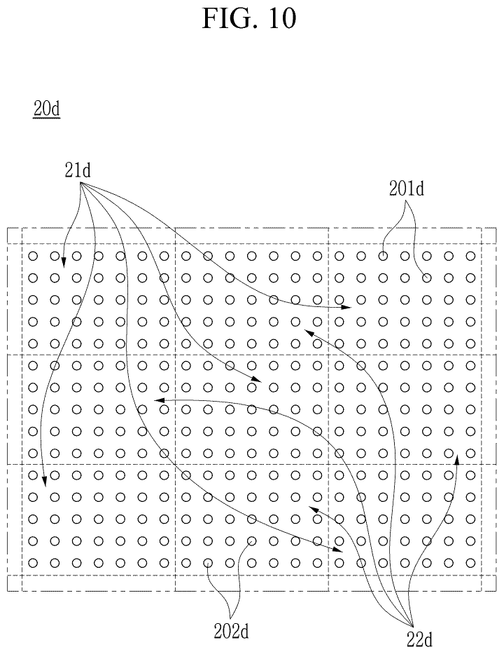

FIG. 10 illustrates a portion of an upper surface of a support member 20d according to some embodiments.

Referring to FIG. 10, an upper surface of the supporting member 20d may include an injection region 21d and an exhaust region 22d.

A plurality of injection regions 21d may be provided. An upper end of the injection hole 201d may be positioned in the injection region 21d. Each of the injection regions 21d may have a predetermined area. Areas of the injection regions 21d may be the same or different from each other. A shape of the injection region 21d may be circular, elliptical, polygonal, or other flat shapes. Shapes of the injection regions 21d may be the same or different from each other.

A plurality of exhaust regions 22d may be provided. An upper end of the exhaust hole 202d may be positioned in the exhaust region 22d. Each of the exhaust regions 22d may have a predetermined area. Areas of the exhaust regions 22d may be the same or different from each other. A shape of the exhaust region 22d may be circular, elliptical, polygonal, or other flat shapes. Shapes of the exhaust regions 22d may be the same or different from each other.

The injection region 21d and the exhaust region 22d may form a boundary, and may be positioned to contact each other. That is, the injection regions 21d may be arranged separately from each other on the upper surface of the support member 20d, and the exhaust regions 22d may be positioned in other regions than the injection regions 21d on the upper surface of the support member 20d,

FIG. 10 illustrates a case where the injection regions 21d and exhaust regions 22d are provided in a rectangular shape, forming a grid-like boundary and positioned to contact each other.

A remaining structure and an operating process of the support member 20d are identical or similar to those described above in FIGS. 1 to 6, so repeated descriptions will be omitted in the interest of brevity.

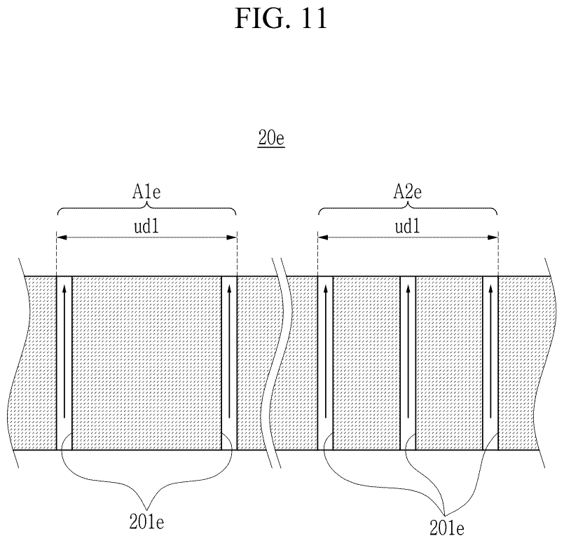

FIG. 11 illustrates a cross-sectional view of a support member 20e according to some embodiments.

Referring to FIG. 11, numbers of upper ends of the injection holes 201e positioned within a unit area of the upper surface of the support member 20e may be provided differently from region to region. Accordingly, an amount of cleaning gas injected from the unit area on the upper surface of the support member 20e may vary by region.

For example, a first region A1e and a second region A2e that are different from each other may be provided on the upper surface of the support member 20e. The first region Ale and the second region A2e may have same areas. Furthermore, a number of upper ends of the injection holes 201e positioned within the first region Ale may be smaller than a number of upper ends of the injection holes 201e positioned within the second region A2e. For convenience, FIG. 11 illustrates an example in which the first region A1e and the second region A2e have a same unit length or width ud1. For example, the first region Ale and the second region A2e may have different radial distances from a center of the upper surface of the support member 20e. That is, the number of the upper ends of the injection holes 201e positioned within the unit area of the upper surface of the support member 20e may vary depending on a distance in a radial direction based on the center of the upper surface of the support member 20e. Furthermore, the first region Ale and the second region A2e may be positioned along a circumferential direction. That is, the number of the upper ends of the injection holes 201e positioned within the unit area of the upper surface of the supporting member 20e may vary depending on a position thereof along the circumferential direction.

For convenience, illustration of the exhaust hole will be omitted in FIG. 11. That is, similarly to what was described above in FIGS. 1 to 8, the exhaust hole may be positioned between adjacent injection holes 201e. Furthermore, similarly to what was described above in FIG. 9 and FIG. 10, there may be no exhaust holes between adjacent injection holes 201e.

A remaining structure and an operating process of the support member 20e are identical or similar to those described above in FIGS. 1 to 6, so repeated descriptions will be omitted in the interest of brevity.

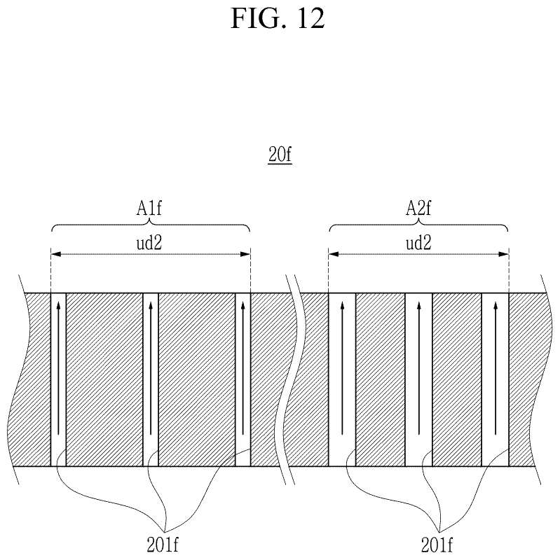

FIG. 12 illustrates a cross-sectional view of a support member 20f according to some embodiments.

Referring to FIG. 12, an area of a flow path intersecting the longitudinal direction of the injection hole 201f positioned within a unit area of an upper surface of the support member 20f in a plan view may vary by region. Accordingly, an amount of cleaning gas injected from the unit area on the upper surface of the support member 20f may vary by region.

For example, a first region A1f and a second region A2f that are different from each other may be provided on the upper surface of the support member 20f. The first region A1f and the second region A2f may have same areas. Furthermore, an area of a flow path intersecting a longitudinal direction of the injection hole 201f positioned within the first region A1f in a plan view may be smaller than an area of a flow path intersecting a longitudinal direction of the injection hole 201f positioned within the second region A2f. For example, the injection hole(s) 201f in the first region A1f may have a smaller diameter or width than the injections hole(s) 201f in the second region A2f. For convenience, FIG. 12 illustrates an example in which the first region A1f and the second region A2f have a same unit length or width ud2.

For example, the first region A1f and the second region A2f may have different radial distances from a center of the upper surface of the support member 20f. That is, the area of the flow path intersecting the longitudinal direction of the injection hole 201f positioned within the unit area of the upper surface of the support member 20f may vary depending on a position in a radial direction based on the center of the upper surface of the support member 20f. Furthermore, the first region A1f and the second region A2f may be positioned along a circumferential direction. That is, the area of the flow path intersecting the longitudinal direction of the injection hole 201f positioned within the unit area of an upper surface of the support member 20f in a plan view may vary depending on a position along a circumferential direction.

For convenience, illustration of the exhaust hole will be omitted in FIG. 12. That is, similarly to what was described above in FIGS. 1 to 8, the exhaust hole may be positioned between adjacent injection holes 201f. Furthermore, similarly to what was described above in FIG. 9 and FIG. 10, there may be no exhaust holes between adjacent injection holes 201f.

A remaining structure and an operating process of the support member 20f are identical or similar to those described above in FIGS. 1 to 6, so repeated descriptions will be omitted in the interest of brevity.

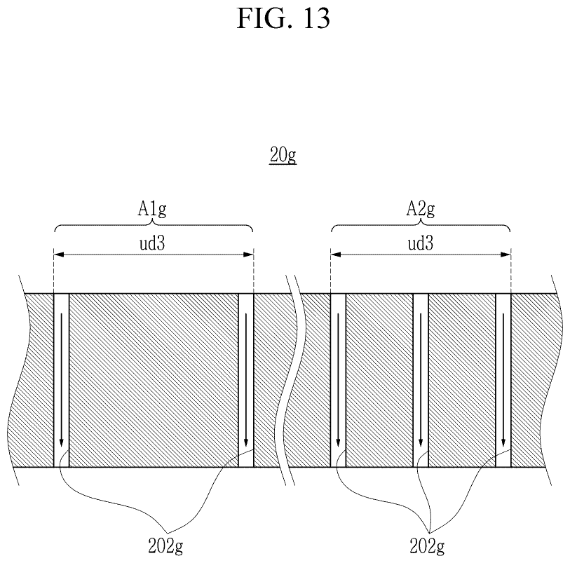

FIG. 13 illustrates a cross-sectional view of a support member 20g according to some embodiments.

Referring to FIG. 13, numbers of upper ends of the exhaust holes 202g positioned within a unit area of the upper surface of the support member 20g may be provided differently from region to region. Accordingly, an amount of cleaning gas exhausted from the unit area on the upper surface of the support member 20g may vary by region.

For example, a first region A1g and a second region A2g that are different from each other may be provided on the upper surface of the support member 20g. The first region A1g and the second region A2g may have same areas. Furthermore, a number of upper ends of the exhaust holes 202g positioned within the first region A1g may be smaller than a number of upper ends of the exhaust holes 202g positioned within the second region A2g. For convenience, FIG. 13 illustrates an example in which the first region A1g and the second region A2g have a same unit length or width ud3. For example, the first region A1g and the second region A2g may have different radial distances from a center of the upper surface of the support member 20g. That is, the number of the upper ends of the exhaust holes 202g positioned within the unit area of the upper surface of the support member 20g may vary depending on a distance in a radial direction based on the center of the upper surface of the support member 20g. Furthermore, the first region A1g and the second region A2g may be positioned along a circumferential direction. That is, the number of the upper ends of the exhaust holes 202g positioned within the unit area of the upper surface of the supporting member 20g may vary depending on a position thereof along the circumferential direction.

For convenience, illustration of the injection hole will be omitted in FIG. 13. That is, similarly to what was described above in FIGS. 1 to 8, the injection hole may be positioned between adjacent exhaust holes 202g. Furthermore, similarly to what was described above in FIG. 9 and FIG. 10, there may be no injection holes between adjacent exhaust holes 202g.

A remaining structure and an operating process of the support member 20g are identical or similar to those described above in FIGS. 1 to 6, so repeated descriptions will be omitted in the interest of brevity.

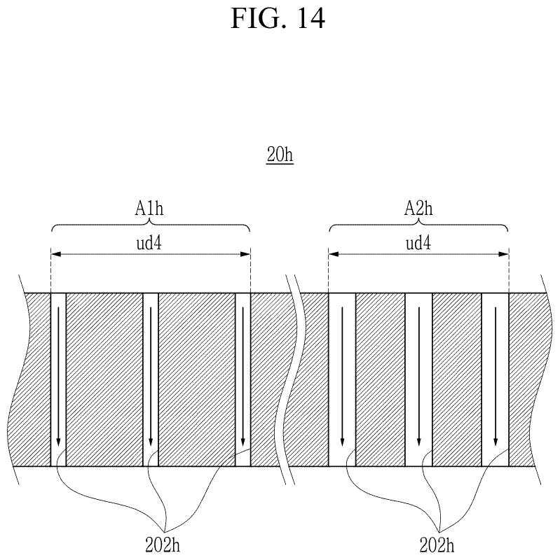

FIG. 14 illustrates a cross-sectional view of a support member 20h according to some embodiments.

Referring to FIG. 14, an area of a flow path intersecting the longitudinal direction of the exhaust hole 202h positioned within a unit area of an upper surface of the support member 20h in a plan view may vary by region. Accordingly, an amount of cleaning gas exhausted from the unit area on the upper surface of the support member 20h may vary by region.

For example, a first region A1h and a second region A1h that are different from each other may be provided on the upper surface of the support member 20h. The first region A1h and the second region A2h may have same areas. Furthermore, an area of a flow path intersecting a longitudinal direction of the exhaust hole 202h positioned within the first region A1h in a plan view may be smaller than an area of a flow path intersecting a longitudinal direction of the exhaust hole 202h positioned within the second region A2h. For example, the exhaust hole(s) 202h in the first region A1h may have a smaller diameter or width than the exhaust hole(s) 202h in the second region A2h. For convenience, FIG. 14 illustrates an example in which the first region A1h and the second region A2h have a same unit length or width ud4.

For example, the first region A1h and the second region A2h may have different radial distances from a center of the upper surface of the support member 20h. That is, the area of the flow path intersecting the longitudinal direction of the exhaust hole 202h positioned within the unit area of the upper surface of the support member 20h may vary depending on a position in a radial direction based on the center of the upper surface of the support member 20h. Furthermore, the first region A1h and the second region A2h may be positioned along a circumferential direction. That is, the area of the flow path intersecting the longitudinal direction of the exhaust hole 202h positioned within the unit area of an upper surface of the support member 20h in a plan view may vary depending on a position along a circumferential direction.

For convenience, illustration of the injection hole will be omitted in FIG. 14. That is, similarly to what was described above in FIGS. 1 to 8, the injection hole may be positioned between adjacent exhaust holes 202h. Furthermore, similarly to what was described above in FIG. 9 and FIG. 10, there may be no injection holes between adjacent exhaust holes 202h.

A remaining structure and an operating process of the support member 20h are identical or similar to those described above in FIGS. 1 to 6, so repeated descriptions will be omitted in the interest of brevity.

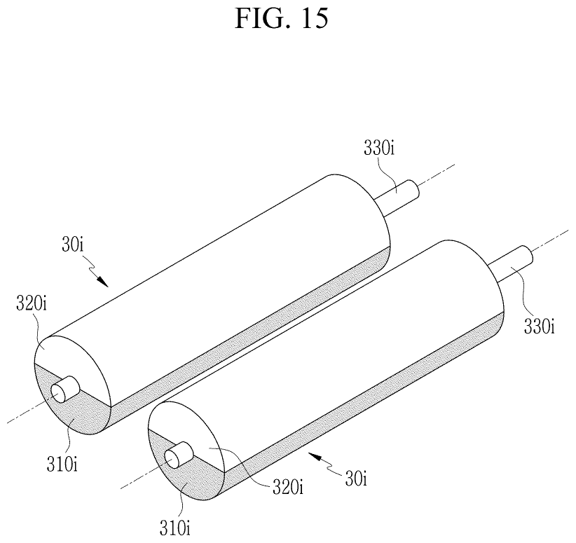

FIG. 15 illustrates a heater 30i according to some embodiments.

Referring to FIG. 15, the heater 30i may have a columnar or cylindrical structure having a predetermined length. The heater 30i may have a cross-sectional shape that is perpendicular to a length thereof, such as a circle, an ellipse, or a polygon. FIG. 15 illustrates an example where a cross-sectional shape along a direction perpendicular to a longitudinal direction is circular.

The heater 30i may have a support shaft 330i connected to a longitudinal center region. A longitudinal direction of the support shaft 330i may be parallel to or coaxial with a longitudinal direction or longitudinal axis of the heater 30i. The support shaft 330i may be disposed such that the longitudinal direction thereof is parallel to the upper surface of the support member 20 described above in FIGS. 1 to 6. The support shaft 330i may be connected to the housing 10 described above.

The heater 30i may be provided to be rotatable around the support shaft 330i. The heater 30i may include a heating portion 310i and a standby portion 320i. The heating portion 310i may be disposed in a portion of an outer circumference of the heater 30i, and the standby portion 320i may be disposed in a remaining portion of the outer circumference of the heater 30i excluding the heating portion 310i. For example, a central angle of the heating portion 310i with respect to a longitudinal central axis of the heater 30i may be 45° or more and 180° or less. The heating portion 310i may be provided so as to irradiate a thermal energy source. The heating portion 310i may include a light emitting diode (LED) lamp, an infrared (IR) lamp, a laser irradiation module, a microwave irradiation module, etc. The heating portion 310i of the heater 30i may be configured to be turned on and off.

When the heater 30i is rotated such that the heating portion 310i faces downward, the heating portion 310i may face the support member 20i to irradiate the thermal energy source toward the support member 20i. Furthermore, when the heating portion 310i of the heater 30i is rotated to face upward, irradiation of the thermal energy source toward the support member 20i may be stopped. Furthermore, the heater 30i may adjust a magnitude of the thermal energy source irradiated toward the support member 20i by adjusting a ratio of a downward-facing portion of the heating portion 310i. Accordingly, the heater 30i may adjust a magnitude of the thermal energy source irradiated toward the substrate S by adjusting a rotation state separately from a change in an on/off state.

Furthermore, a plurality of heaters 30i may be provided, and may be disposed separately from each other. A direction in which the heaters 30i are spaced from each other may be a direction intersecting a longitudinal direction of the heaters 30i. The direction in which the heaters 30i are spaced from each other may be a direction that is perpendicular to the longitudinal direction of the heaters 30i. Furthermore, the direction in which the heaters 30i are spaced apart from each other may be a direction that is parallel to an upper surface of the supporting member 20i described above.

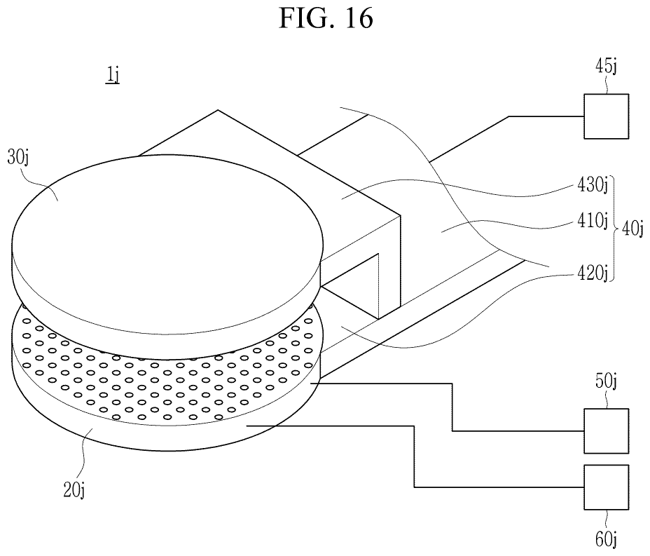

FIG. 16 illustrates a perspective view of a substrate support apparatus 1j according to some embodiments.

Referring to FIG. 16, the substrate support apparatus 1j according to some embodiments may include a support member 20j, a heater 30j, and a transfer arm 40j.

A fluid supply member 50j may be connected to the support member 20j. The exhaust member 60j may be connected to the support member 20j.

A structure and an operation of the support member 20j, the fluid supply member 50j, and the exhaust member 60j are identical or similar to those described above in FIGS. 1 to 14, and therefore repeated descriptions will be omitted in the interest of brevity.

A structure and an operation of the heater 30j are identical or similar to the heater 30 described above in FIGS. 1 to 6, and therefore repeated descriptions will be omitted in the interest of brevity. Furthermore, the structure and operation of the heater 30j may be identical or similar to the heater 30i described above in FIG. 15. In this case, the heater 30j may have a structure in which the above-described support shaft 330i is connected to the transfer arm 40j. FIG. 16 illustrates an example in which the heater 30j has a structure identical or similar to that of the heater 30 described above in FIGS. 1 to 6.

The transfer arm 40j may be connected to the support member 20j. The transfer arm 40j may be connected to an outer surface or lower surface of the support member 20j. Furthermore, the transfer arm 40j may be connected to the heater 30j. The transfer arm 40j may be connected to the driving member 45j. The transfer arm 40j may be provided movably.

The driving member 45j may provide power to move the transfer arm 40j, and the support member 20j and the heater 30j connected to the transfer arm 40j. For example, the driving member 45j may include a motor, a hydraulic cylinder, or the like.

The transfer arm 40j may include a main support 410j, a first branch 420j, and a second branch 420j. The main support 410j may be connected to the driving member 45j. The first branch 420j may be branched from the main support 410j. The first branch 420j may connect the main support 410j and the support member 20j. The first branch 420j may be connected to an outer surface or lower surface of the support member 20j. The second branch 430j may be branched from the main support 410j. The second branch 430j may connect the main support 410j and the heater 30j. When the heater 30j has a structure identical or similar to the heater 30 described above in FIGS. 1 to 6, the second branch 430j may be connected to an outer surface or upper surface of the heater 30j. When the heater 30j has a structure identical or similar to the heater 30i described above in FIG. 15, the support shaft 330i described above may be connected to the second branch 430j.

While the present disclosure has been described in connection with what is presently considered to be practical embodiments, it is to be understood that the disclosure is not limited to the disclosed example embodiments, but, on the contrary, is intended to cover various modifications and equivalent dispositions included within the spirit and scope of the appended claims.

What is claimed is:

1. A substrate support apparatus comprising
a support member configured to support a substrate on a substrate support surface,
wherein the support member has a plurality of injection holes, each having a first end that is positioned on the substrate support surface and configured to inject a cleaning gas, and a plurality of exhaust holes, each having a first end that is positioned on the substrate support surface and configured to enable exhaust.

2. The substrate support apparatus of claim 1, further comprising
a heater facing the support member and spaced apart from the support member.

3. The substrate support apparatus of claim 2, wherein
the heater has a columnar structure and is configured to rotate around a support axis,
wherein the heater includes:
a heating portion in a portion of an outer circumference of the columnar structure configured to irradiate a thermal energy source; and
a standby portion disposed in a remaining portion of the outer circumference of the columnar structure excluding the heating portion.

4. The substrate support apparatus of claim 1, further comprising
a housing configured to have an opening positioned at a first side thereof,
the support member is inside the housing.

5. The substrate support apparatus of claim 1, further comprising
a fluid supply member connected to the injection holes and configured to supply a cleaning gas, which is an inert gas.

6. The substrate support apparatus of claim 1, wherein
first ends of the injection holes are distributed at different positions on the substrate support surface, and
first ends of the exhaust holes are distributed at different positions on the substrate support surface.

7. The substrate support apparatus of claim 1, wherein
the substrate support surface includes an injection region and an exhaust region,
first ends of the injection holes are positioned in the injection region, and
first ends of the exhaust holes are positioned in the exhaust region.

8. The substrate support apparatus of claim 7, wherein
the injection region and the exhaust region include a central circle and at least one concentric ring surrounding the central circle.

9. The substrate support apparatus of claim 1, wherein
a number of first ends of the injection holes positioned within a unit area of the substrate support surface varies from region to region.

10. The substrate support apparatus of claim 1, wherein
a diameter or width of the injection holes positioned within a unit area of the substrate support surface varies from region to region.

11. The substrate support apparatus of claim 1, wherein
a number of first ends of the exhaust holes positioned within a unit area of the substrate support surface varies from region to region.

12. The substrate support apparatus of claim 1, wherein
a diameter or width of the exhaust holes positioned within a unit area of the substrate support surface varies from region to region.

13. The substrate support apparatus of claim 1, wherein
first ends of the exhaust holes positioned on the substrate support surface are provided in a ring structure to be positioned on an outer circumference region of the substrate support surface and first ends of the injection holes positioned on the substrate support surface are provided in a central region of the substrate support surface.

14. The substrate support apparatus of claim 1, wherein
first ends of the injection holes positioned on the substrate support surface are provided in a ring structure to be positioned on an outer circumference region of the substrate support surface and first ends of the exhaust holes positioned on the substrate support surface are provided in a central region of the substrate support surface.

15. The substrate support apparatus of claim 1, further comprising
a transfer arm connected to the support member.

16. A substrate support apparatus comprising:
a support member configured to support a substrate on a substrate support surface;
a heater facing the support member and spaced apart from the support member; and
a transfer arm connected to the support member and the heater,
wherein the support member has a plurality of injection holes, each having a first end that is positioned on the substrate support surface and configured to inject a cleaning gas, and a plurality of exhaust holes, each having a first end that is positioned on the substrate support surface and configured to enable exhaust.

17. The substrate support apparatus of claim 16, further comprising
a fluid supply member connected to the injection holes and configured to supply a cleaning gas that is at least partially phase-changed into a solid state by adiabatic expansion after being injected from the injection holes.

18. The substrate support apparatus of claim 16, further comprising
a driving member connected to the transfer arm and configured to provide power for moving the transfer arm.

19. A substrate support apparatus comprising:
a housing;
a support member inside the housing and configured to support a substrate on a substrate support surface;
a heater inside the housing spaced apart from the support member; and
a transfer arm connected to the housing,
wherein the support member has a plurality of injection holes, each having a first end that is positioned on the substrate support surface and configured to inject a cleaning gas that is at least partially phase-changed into a solid state by adiabatic expansion after being injected, and a plurality of exhaust holes, each having a first end that is positioned on the substrate support surface and configured to enable exhaust.

20. The substrate support apparatus of claim 19, further comprising:
a driving member connected to the transfer arm and configured to provide power to move the transfer arm; and
a fluid supply member connected to the injection holes and configured to supply a cleaning gas.
